(19) United States
(12) Patent Application Publication
(10) Pub. No.: US 2024/0032302 A1
(43) Pub. Date: Jan. 25, 2024

(54) NON-VOLATILE MEMORY DEVICE

(71) Applicant: SK hynix Inc., Icheon-si Gyeonggi-do (KR)

(72) Inventors: Woo Cheol LEE, Icheon-si Gyeonggi-do (KR); Mi R IM, Icheon-si Gyeonggi-do (KR)

(73) Assignee: SK hynix Inc., Icheon-si Gyeonggi-do (KR)

(21) Appl. No.: 18/088,172

(22) Filed: Dec. 23, 2022

(30) Foreign Application Priority Data
Jul. 21, 2022 (KR) 10-2022-0090104

(51) Int. Cl. H10B 51/20; H10B 51/30

(52) U.S. Cl. CPC H01L 27/11597; H01L 27/1159

(57) ABSTRACT

A non-volatile memory device includes: a substrate; a gate structure including a plurality of gate electrode layers and a plurality of interlayer insulating layers, which are alternately stacked in a vertical direction on the substrate, the gate structure including a hole pattern; a data storage layer disposed inside the hole pattern; and a channel layer disposed on the data storage layer inside the hole pattern. The channel layer is disposed at each of different levels isolated from each other in the vertical direction by the plurality of interlayer insulating layers.

### CROSS-REFERENCE TO RELATED APPLICATION

The present application claims priority under 35 U.S.C. § 119(a) to Korean patent application number 10-2022-0090104, filed on Jul. 21, 2022, in the Korean Intellectual Property Office, the entire disclosure of which is incorporated herein by reference.

### BACKGROUND

### 1. Technical Field

The present disclosure generally relates to a non-volatile memory device, and more particularly, to a three-dimensional non-volatile memory device.

### 2. Related Art

According to the tendency of a decrease in design rule and an increase in degree of integration, studies on non-volatile memory device structures capable of guaranteeing structural stability and reliability of a signal storing operation have been continuously conducted. That is, a technique for increasing the degree of integration of memory cells through a decrease in memory cell area and a technique for improving reliability of stored information by preventing signal interference between adjacent memory cells have been researched.

### SUMMARY

In accordance with an embodiment of the present disclosure, there may be provided a non-volatile memory device including: a substrate; a gate structure including a plurality of gate electrode layers and a plurality of interlayer insulating layers, which are alternately stacked in a vertical direction over the substrate, the gate structure including a hole pattern; a data storage layer disposed inside the hole pattern; and a channel layer disposed on the data storage layer inside the hole pattern, wherein the channel layer is disposed at each of different levels isolated from each other in the vertical direction by the plurality of interlayer insulating layers.

In accordance with an embodiment of the present disclosure, there may be provided a non-volatile memory device including: a gate structure including a plurality of gate electrode layers and a plurality of interlayer insulating layers, which are alternately stacked in a vertical direction over a substrate; a channel layer disposed on the substrate, the channel layer disposed adjacent to each of the plurality of gate electrode layers of the gate structure; a data storage layer disposed between each of the plurality of gate electrode layers and the channel layer; and a first source/drain pillar and a second source/drain pillar, penetrating the gate structure, wherein each of the data storage layer and the channel layer is discontinuous in the vertical direction, each of the data storage layer and the channel layer being formed at levels in which each of the plurality of gate electrode layers is formed.

### BRIEF DESCRIPTION OF THE DRAWINGS

Various examples of embodiments will now be described more fully hereinafter with reference to the accompanying drawings; however, they may be embodied in different forms and should not be construed as limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it may be the only element between the two elements, or additional intervening elements may also be present. Like reference numerals refer to like elements throughout the drawings.

FIG. 1 is a plan view illustrating a layout of a non-volatile memory device in accordance with an embodiment of the present disclosure.

FIGS. 2A to 2C are views of the non-volatile memory device shown in FIG. 1.

FIG. 3 is a plan view illustrating a layout of a non-volatile memory device in accordance with an embodiment of the present disclosure.

FIG. 4A is a sectional view of the non-volatile memory device taken along line B-B′ shown in FIG. 3. FIG. 4B is a plan view of the non-volatile memory device shown in FIG. 3.

FIG. 5 is a plan view illustrating a layout of a non-volatile memory device in accordance with an embodiment of the present disclosure.

FIG. 6A is a sectional view of the non-volatile memory device taken along line C-C′ shown in FIG. 5. FIG. 6B is a plan view of the non-volatile memory device shown in FIG. 5.

FIGS. 7A to 7K are sectional views illustrating a manufacturing method of a non-volatile memory device in accordance with an embodiment of the present disclosure.

FIGS. 8, 9A, and 9B are views illustrating an operating method of a non-volatile memory device in accordance with an embodiment of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first”, “second”, etc. may be used herein to describe various elements, these elements are not limited by these terms. These terms are used for distinguishing one element from another element and not to suggest a number or order of elements.

Embodiments provide a non-volatile memory device including memory cells stacked in a three-dimensional structure.

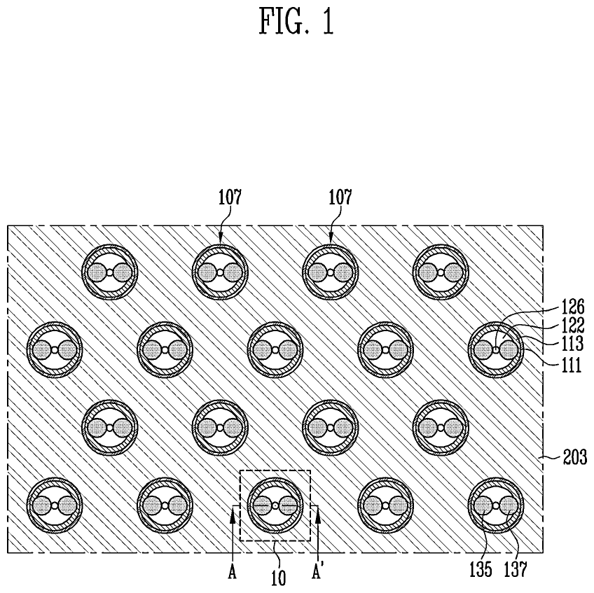

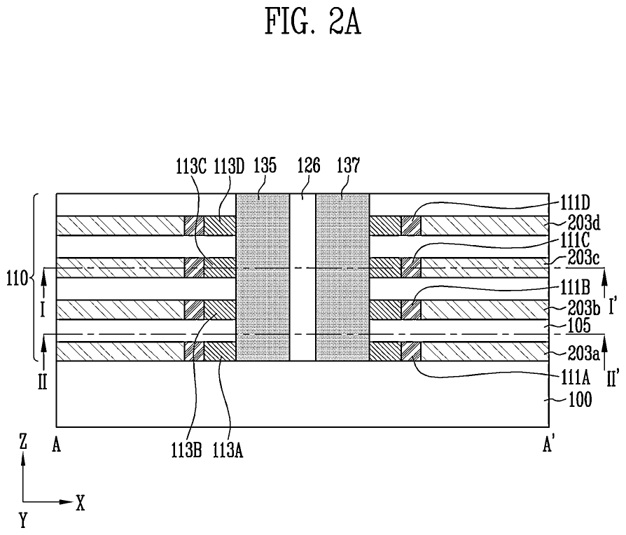

FIG. 1 is a plan view illustrating a layout of a non-volatile memory device in accordance with an embodiment of the present disclosure.

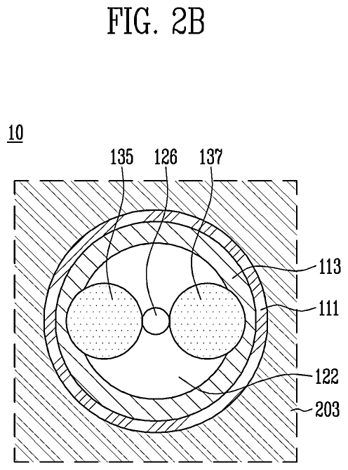

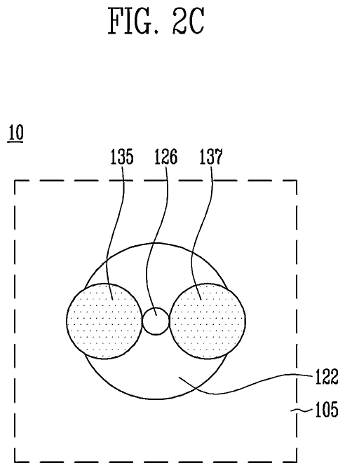

FIGS. 2A to 2C are views of the non-volatile memory device, shown in FIG. 1. FIG. 2A is a sectional view of the non-volatile memory device taken along line A-A′ shown in FIG. 1. FIGS. 2B and 2C are plan views of a partial region 10 of the non-volatile memory device taken along lines I-I′ and II-II′, shown in FIG. 2A.

Referring to FIGS. 1 and 2A to 2C, the non-volatile memory device in accordance with the embodiment of the present disclosure may be a ferroelectric memory device. The non-volatile memory device may include a substrate 100, a gate structure 110 that is disposed over the substrate 100 and includes a hole pattern 107, a data storage layer 111 that is disposed along a sidewall surface of the gate structure 110 inside the hole pattern 107, and a channel layer 113 that is disposed on the data storage layer 111 inside the hole pattern 107.

The gate structure 110 may include a plurality of gate electrode layers 203 and a plurality of interlayer insulating layers 105, which are alternately stacked in a Z direction over the substrate 100. The Z direction may be a vertical direction with respect to the substrate 100. The plurality of gate electrode layers 203 may include first to fourth gate electrode layers 203a, 203b, 203c, and 203d. Hereinafter, for convenience of description, a structure of the non-volatile memory device is described based on an embodiment including the first to fourth gate electrode layers 203a, 203b, 203c, and 203d. However, in the embodiment of the present disclosure, the number of gate electrode layers is not limited to 4 and may vary based on the embodiment.

The gate structure 110 may include a plurality of hole patterns 107, and the plurality of hole patterns 107 may be disposed while being spaced apart from each other. The non-volatile memory device may include memory units that are distinguished from each other for each hole pattern 107. The memory units that are distinguished from each other for each hole pattern 107 may be independently driven. The plurality of hole patterns 107 may be arranged in various structures. In an embodiment, the plurality of hole patterns 107 may be arranged in zigzag in the gate electrode layer 203. The planar shape of the plurality of hole patterns 107 may vary based on the embodiment. In an embodiment, as shown in the drawings, the plurality of hole patterns 107 may have a circular shape. In another embodiment, although not shown in the drawings, the plurality of hole patterns 107 may have an elliptical or polygonal planar shape.

The data storage layer 111 may be disposed to be discontinuous in the Z direction. More specifically, the data storage layer 111 may include first to fourth memory parts 111A, 111B, 111C, and 111D, which are formed at four different levels. The levels at which the first to fourth memory parts 111A, 111B, 111C, and 111D are formed may respectively coincide with levels at which the first to fourth gate electrode layers 203a, 203b, 203c, and 203d are formed. In other words, each memory part may be formed on the same level as the corresponding gate electrode layer. Each of the first to fourth memory parts 111A, 111B, 111C, and 111D may cover a sidewall surface of a corresponding gate electrode layer, among the first to fourth gate electrode layers 203a, 203b, 203c, and 203d.

The channel layer 113 may be disposed to be discontinuous in the Z direction. More specifically, the channel layer 113 may include first to fourth cell parts 113A, 113B, 113C, and 113D, which are formed at four different levels. The levels at which the first to fourth cell parts 113A, 113B, 113C, and 113D are formed may respectively coincide with the levels at which the first to fourth gate electrode layers 203a, 203b, 203c, and 203d are formed. In other words, each cell part may be formed on the same level as the corresponding gate electrode layer. The first to fourth cell parts 113A, 113B, 113C, and 113D may be disposed to be in contact with the first to fourth memory parts 111A, 111B, 111C, and 111D. In other words, the channel layer 113 may be disposed to be in contact with the data storage layer 111, and the data storage layer 111 may be disposed between the channel layer 113 and the gate electrode layer 203.

Each of the data storage layer 111 and the channel layer 113 may be discontinuous in the Z direction. More specifically, the plurality of interlayer insulating layers 105 may protrude farther into the hole pattern 107 compared to the plurality of gate electrodes 203 (i.e., the first to fourth gate electrode layers 203a, 203b, 203c, and 203d in the embodiment). The hole pattern 107 may include a plurality of concave parts that are defined at the same levels as the plurality of gate electrode layers 203. Each concave part may be defined between a plurality of interlayer insulating layers 105 that overlap with each other in the Z direction. Specifically, the plurality of interlayer insulating layers 105 may include a first interlayer insulating layer and a second interlayer insulating layer, which are adjacent to each other in the Z direction, and the concave part may be defined between the first interlayer insulating layer and the second interlayer insulating layer. Each of the data storage layer 111 and the channel layer 113 may be disposed at the concave part between the first interlayer insulating layer and the second interlayer insulating layer. In other words, the first to fourth cell parts 113A, 113B, 113C, and 113D may be respectively disposed at different levels, isolated from each other in the Z direction by the plurality of interlayer insulating layers 105, and the first to fourth memory parts 111A, 111B, 111C, and 111D may be respectively disposed at different levels, isolated from each other in the Z direction by the plurality of interlayer insulating layers 105.

The data storage layer 111 may be a ferroelectric memory layer. That is, the data storage layer 111 may include ferroelectrics. The ferroelectrics may be a material having a spontaneous electrical polarization in a state in which no external electric field is applied.

In an embodiment, the ferroelectrics may represent polarization hysteresis behavior including a switching operation of the electrical polarization when an external electric field is applied. After the external electric field is removed, the ferroelectrics may maintain, in a non-volatile manner, any one of two stabilized residual polarizations that are generated as a result of the polarization hysteresis behavior. The two stabilized residual polarizations may have different polarization orientations. Such a residual polarization characteristic may be used to store signal information of “0” and “1” in the non-volatile manner. The ferroelectrics may be, for example, hafnium oxide, zirconium oxide, hafnium zirconium oxide, or any combination of two or more thereof.

The non-volatile memory device may include a first insulating pillar 122, a second insulating pillar 126, a first source/drain pillar 135, and a second source/drain pillar 137, which are disposed in a central region of the hole pattern 107. The first insulating pillar 122 may be formed on the channel layer 113 inside the hole pattern 107.

The second insulating pillar 126 may be disposed between the first source/drain pillar 135 and the second source/drain pillar 137. The first source/drain pillar 135 and the second source/drain pillar 137 may be electrically insulated from each other by the second insulating pillar 126.

The first source/drain pillar 135 and the second source/drain pillar 137 may penetrate the first insulating pillar 122. In an embodiment, the first source/drain pillar 135 and the second source/drain pillar 137 may penetrate portions of the channel layer 113. A current having a predetermined magnitude may flow through the channel layer 113 by applying a voltage between the first source/drain pillar 135 and the second source/drain pillar 137.

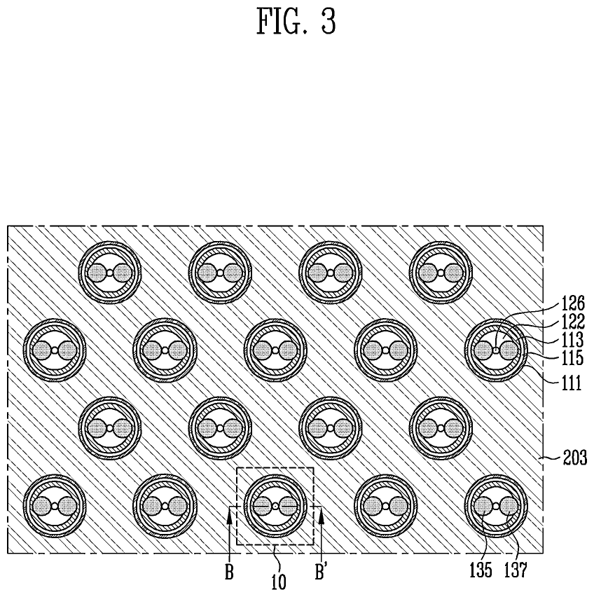

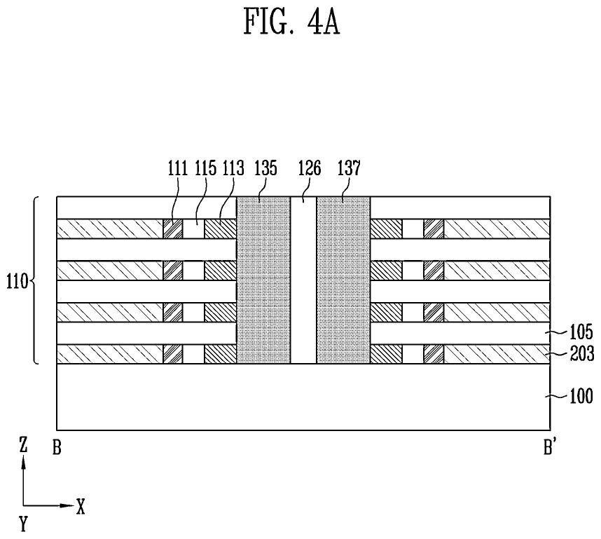

FIG. 3 is a plan view illustrating a layout of a non-volatile memory device in accordance with an embodiment of the present disclosure.

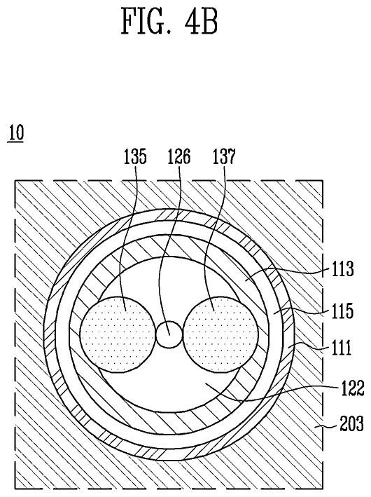

FIG. 4A is a sectional view of the non-volatile memory device, taken along line B-B′, shown in FIG. 3. FIG. 4B is an enlarged plan view of a partial region 10 of the non-volatile memory device, shown in FIG. 3.

Referring to FIGS. 3, 4A, and 4B, the other components except a dielectric layer 115 are substantially the same as the components of the non-volatile memory device described with reference to FIGS. 1 and 2A to 2C. For example, as described with reference to FIGS. 1 and 2A to 2C, the non-volatile memory device may include a substrate 100, a gate structure 110 including a plurality of gate electrode layers 203 and a plurality of interlayer insulating layers 105, which are penetrated by a hole pattern, a data storage layer 111, a channel layer 113, a first insulating pillar 122, a second insulating pillar 126, a first source/drain pillar 135, and a second source/drain pillar 137.

The dielectric layer 115 may be an interface insulating layer. The dielectric layer 115 may include an insulating material. The dielectric layer 115 may serve as a barrier layer for preventing material diffusion between the channel layer 113 and ferroelectrics as the data storage layer 111. Also, when the data storage layer 111 and the channel layer 113 have difference lattice constants, the dielectric layer 115 may block direct contact between the data storage layer 111 and the channel layer 113. As a result, a crystal defect due to a lattice mismatch may be prevented from occurring at an interface between the data storage layer 111 and the channel layer 113 or the crystal defect may be mitigated. As the density of the crystal defect increases, the reliability of a polarization switching operation of the data storage layer 111 may deteriorate, and the durability of the polarization switching operation may be degraded. The dielectric layer 115 may reduce the occurrence of the crystal defect so that the reliability and durability of the polarization switching operation of the data storage layer 111 may be improved.

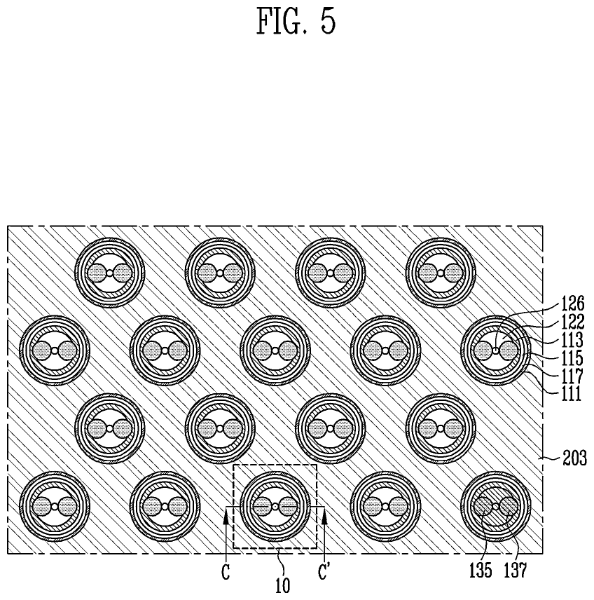

FIG. 5 is a plan view illustrating a layout of a non-volatile memory device in accordance with an embodiment of the present disclosure.

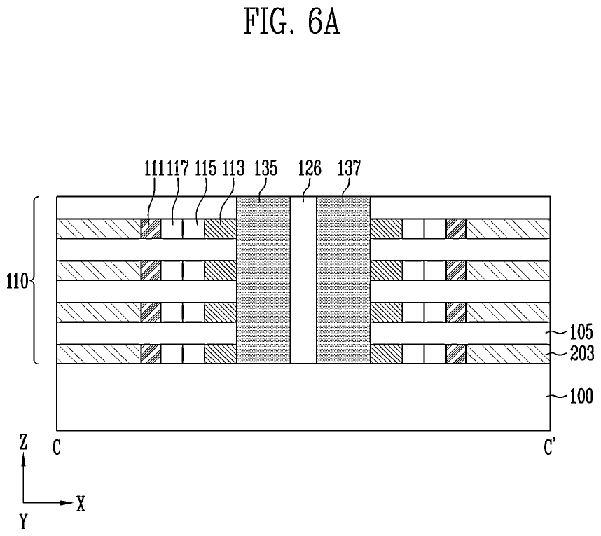

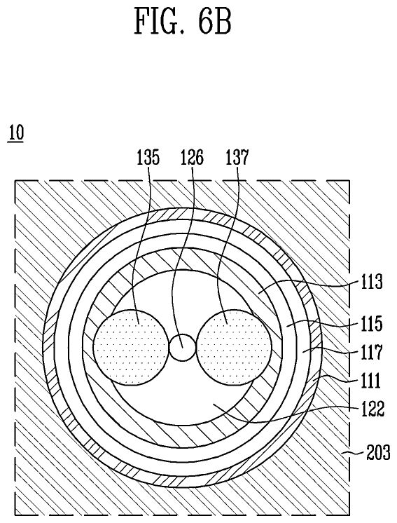

FIG. 6A is a sectional view of the non-volatile memory device, taken along line C-C′, shown in FIG. 5. FIG. 6B is an enlarged plan view of a partial region 10 of the non-volatile memory device, shown in FIG. 5.

Referring to FIGS. 5, 6A, and 6B, the other components other than a dielectric layer 115 and a metal layer 117 are substantially the same as the components of the non-volatile memory device, described with reference to FIGS. 1 and 2A to 2C. For example, as described with reference to FIGS. 1 and 2A to 2C, the non-volatile memory device may include a substrate 100, a gate structure 110 including a plurality of gate electrode layers 203 and a plurality of interlayer insulating layers 105, a data storage layer 111, a channel layer 113, a first insulating pillar 122, a second insulating pillar 126, a first source/drain pillar 135, and a second source/drain pillar 137. The plurality of gate electrode layers 203 and the plurality of interlayer insulating layers 105 of the gate structure 110 may be penetrated by a hole pattern.

The dielectric layer 115 may be substantially the same as the dielectric layer 115 of the non-volatile memory device, described with reference to FIGS. 3, 4A, and 4B.

The metal layer 117 may perform a similar function as the dielectric layer 115. Alternatively, the metal layer 117 may be disposed between the channel layer 113 and the data storage layer 111 to perform a function of reinforcing a polarization state of ferroelectrics as the data storage layer 111.

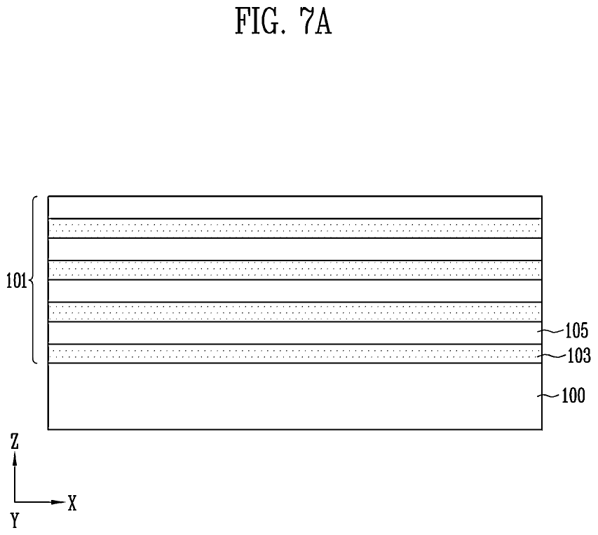

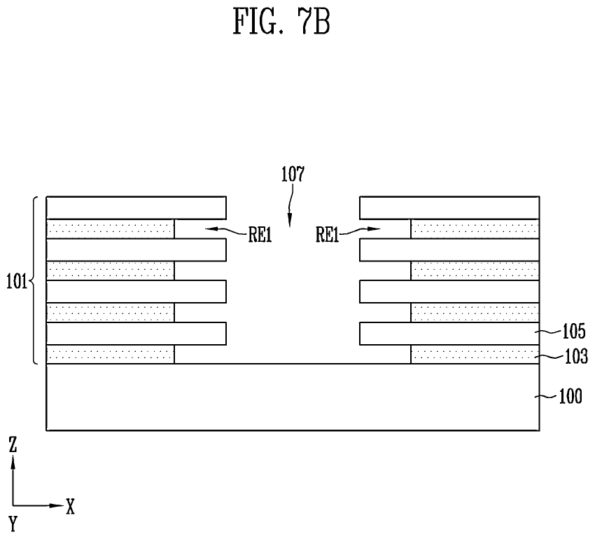

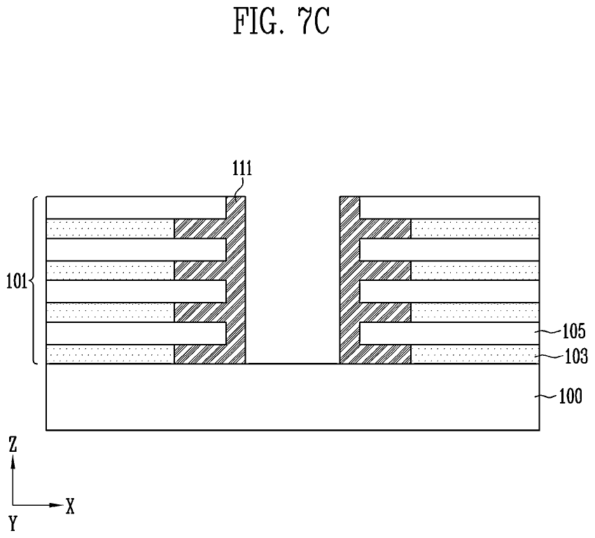

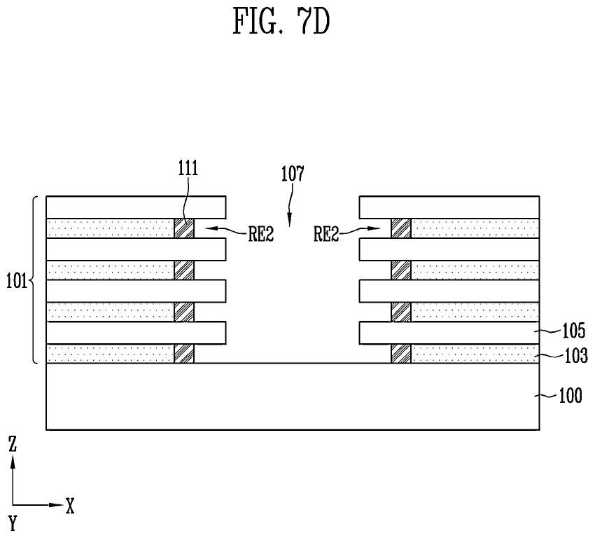

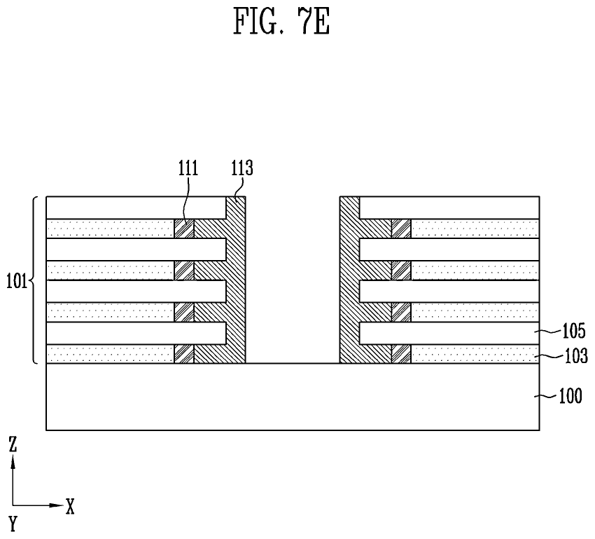

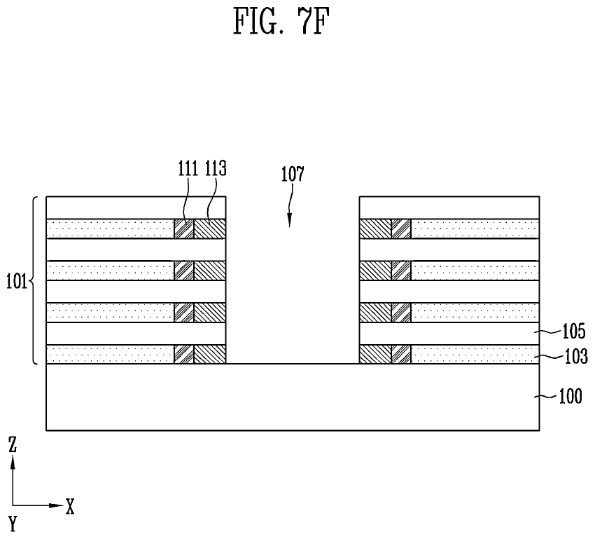

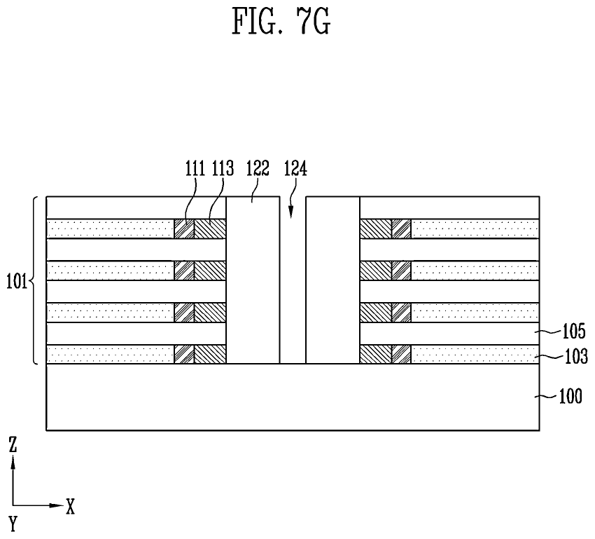

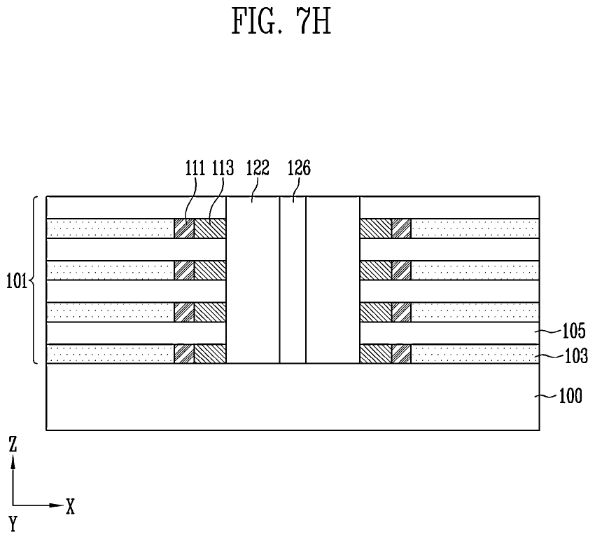

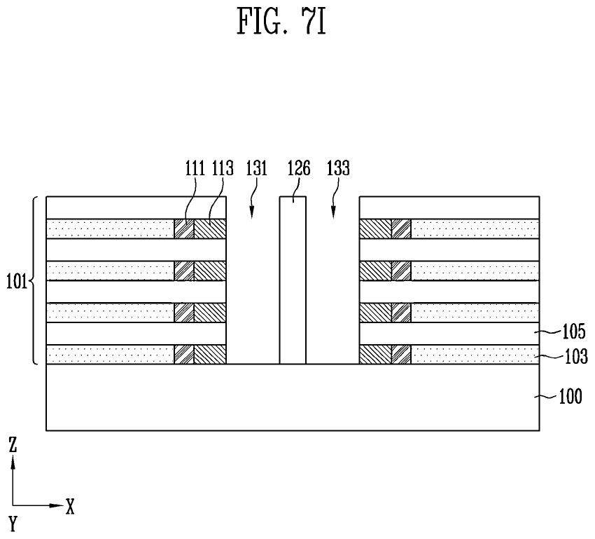

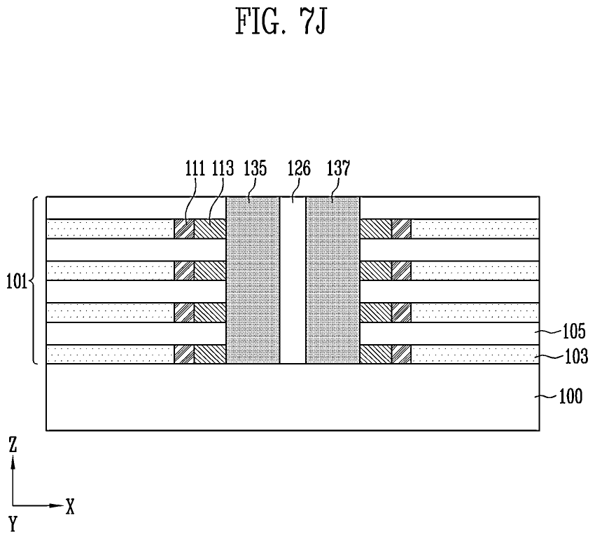

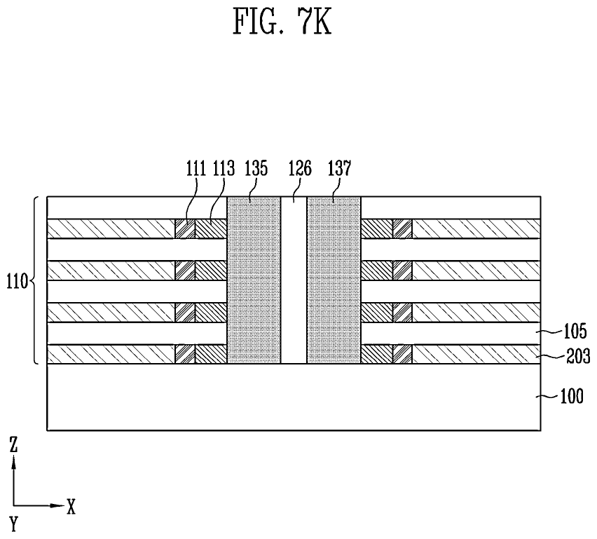

FIGS. 7A to 7K are sectional views illustrating a manufacturing method of a non-volatile memory device in accordance with an embodiment of the present disclosure. FIGS. 7A to 7K are sectional views, taken along the line A-A′, shown in FIG. 1. The manufacturing method described below may be applied to manufacturing of the non-volatile memory devices, described with reference to FIGS. 1 to 6B.

Referring to FIG. 7A, a stack structure 101 may be formed on a substrate 100. The stack structure 101 may include a plurality of sacrificial insulating layers 103 and a plurality of interlayer insulating layer 105, which are alternately stacked in the Z direction.

The sacrificial insulating layers 103 may be formed of an insulating material for sacrificial insulating layers, and the interlayer insulating layers 105 may be formed of an insulating material for interlayer insulating layers. The sacrificial insulating layers 103 may be formed of a material that is different from the material of the interlayer insulating layers 105. More specifically, the sacrificial insulating layers 103 may be formed of a material that can be etched while minimizing etching of the interlayer insulating layers 105 in a process of selectively etching the sacrificial insulating layers 103. In other words, the sacrificial insulating layers 103 may be formed of a material having a large etch rate difference from the interlayer insulating layers 105. For example, the sacrificial insulating layers 103 may be formed of a nitride layer, such as a silicon nitride layer (SiN), and the interlayer insulating layers may be formed of an oxide layer, such as a silicon oxide layer (S102).

Referring to FIG. 7B, a hole pattern 107 may formed by patterning the stack structure 101 over the substrate 100. The hole pattern 107 may penetrate the stack structure 101 to expose the substrate 100. Although not shown in the drawing, the hole pattern 107 may have a circular, elliptical, or polygonal planar shape.

A portion of each of the sacrificial insulating layers 103 may be selectively etched, thereby forming a first concave part RE1. The first concave part RE1 may be disposed at the same level as each of the sacrificial insulating layers 103. In an embodiment, a wet etching process may be used for the etching of the sacrificial insulating layers 103. Accordingly, a sidewall surface of the stack structure 101 may have an uneven or winding shape inside the hole pattern 107. The plurality of interlayer insulating layers 105 may have a shape that protrudes farther into the hole pattern 107 compared to the plurality of sacrificial insulating layers 103.

Referring to FIG. 7C, a data storage layer 111 may be formed along an inner wall surface of the stack structure 101 inside the hole pattern (107 shown in FIG. 7B). The data storage layer 111 may be formed to have a predetermined thickness along the uneven or winding shape of the inner wall surface of the stack structure 101. The data storage layer 111 may include ferroelectrics. In an embodiment, the data storage layer 111 may fill the first concave part RE1, shown in FIG. 7B.

Referring to FIG. 7D, a portion of the data storage layer 111 may be removed. The data storage layer 111 may remain in a form in which the data storage layer 111 partially fills the first concave part (RE1 shown in FIG. 7B) of the hole pattern 107. The other portion of the first concave part (RE1 shown in FIG. 7B), which is not filled with the data storage layer 111, but opened, may be defined as a second concave part RE2.

Referring to FIG. 7E, a channel layer 113 may be formed along the inner wall surface of the stack structure 101 and the data storage layer 111 inside the hole pattern (107 shown in FIG. 7D). The channel layer 113 may be formed to have a predetermined thickness along the uneven or winding shape of the inner wall surface of the stack structure 101. In an embodiment, the channel layer 113 may fill the second concave part RE2, shown in FIG. 7D. In another embodiment, in order to provide the non-volatile memory device, shown in FIGS. 3, 4A, and 4B, the dielectric layer 115, shown in FIGS. 3, 4A, and 4B may be formed in a portion of the second concave part RE2 before the channel layer 113 is formed. In still another embodiment, in order to provide the non-volatile memory device, shown in FIGS. 5, 6A, and 6B, the dielectric layer 115 and the metal layer 117, which are shown in FIGS. 5, 6A, and 6B, may be formed in a portion of the second concave part RE2 before the channel layer 113 is formed.

Referring to FIG. 7F, a planarization process of removing a portion of the channel layer 113, which is formed at the outside of the second concave part (RE2 shown in FIG. 7D), may be formed. The channel layer 113 may remain in a form in which the channel layer 113 fills the second concave part (RE2 shown in FIG. 7D) inside the hole pattern 107.

Referring to FIG. 7G, a first insulating pillar 122 may be formed inside the hole pattern 107. Subsequently, a first opening 124 may be formed to penetrate the first insulating pillar 122. The first opening 124 may penetrates the center of the first insulating pillar 122. In an embodiment, the first opening 124 may have a circular shape.

Referring to FIG. 7H, the first opening 124 may be filled with an insulating material, thereby forming a second insulating pillar 126.

Referring to FIG. 7I, a second opening 131 and a third opening 133 may be formed to penetrate the first insulating pillar 122. In an embodiment, the second opening 131 and the third opening 133 may have a circular shape.

Referring to FIG. 73, the second opening 131 and the third opening 133 may be filled with a conductive material, thereby forming a first source/drain pillar 135 and a second source/drain pillar 137. The second insulating pillar 126 may be disposed between the first source/drain pillar 135 and the second source/drain pillar 137. The first source/drain pillar 135 and the second source/drain pillar 137 may be isolated from each other by the second insulating pillar 126.

Referring to FIG. 7K, the sacrificial insulating layers 103, shown in FIG. 7J, may be selectively removed by using an etch selectivity with respect to the interlayer insulating layers 105. In an embodiment, a slit (not shown) may be formed to penetrate the stack structure 101, shown in FIG. 7J. The sacrificial insulating layers 103, shown in FIG. 7J may be exposed by the slit. Therefore, the sacrificial insulating layers 103, shown in FIG. 7J, may be removed through a wet etching process through the slit.

Subsequently, a conductive material may be filled in regions in which the sacrificial insulating layers 103, shown in FIG. 7J, are removed, thereby forming gate electrode layers 203. The gate electrode layers 203 may include at least one of a doped silicon layer, a metal silicide layer, and a metal layer. A low resistance metal, such as tungsten, may be used for each of the gate electrode layers 203 to achieve low resistance wiring. Each of the gate electrode layers 203 may further include a barrier layer, such as a titanium nitride layer, a tungsten nitride layer, or a tantalum nitride layer.

Through the above-described process, a gate structure 110 including the gate electrode layers 203 and the interlayer insulating layers 105 may be formed.

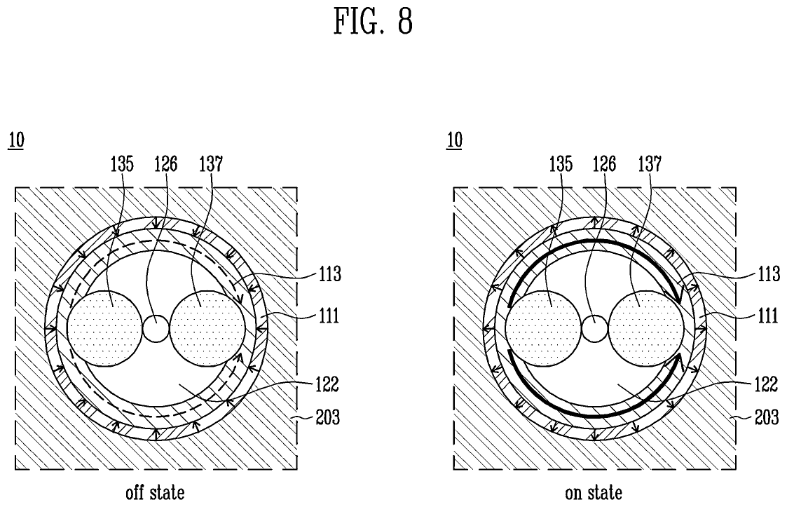

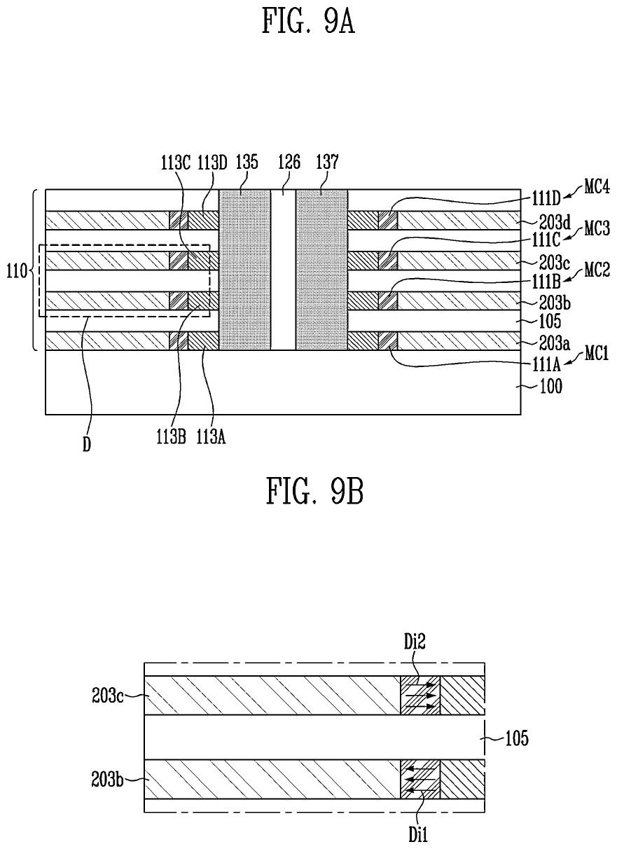

FIGS. 8, 9A, and 9B are views illustrating an operating method of a non-volatile memory device in accordance with an embodiment of the present disclosure.

FIG. 8 illustrates flows of current in a channel layer 113 in an off-state and an on-state and an internal polarization state in a data storage layer 111 according thereto.

Referring to FIGS. 9A and 9B, the non-volatile memory device may include first to fourth memory cells MC1, MC2, MC3, and MC4. Each of the first to fourth memory cells MC1, MC2, MC3, and MC4 may be provided as in a transistor form. The first to fourth memory cells MC1, MC2, MC3, and MC4 may be connected in series to each other and may constitute a string. The first memory cell MC1 may include a first gate electrode layer 203a, a first memory part 111A of a data storage layer 111, and a first cell part 113A of a channel layer 113. The second memory cell MC2 may include a second gate electrode layer 203b, a second memory part 111B of the data storage layer 111, and a second cell part 113B of the channel layer 113. The third memory cell MC3 may include a third gate electrode layer 203c, a third memory part 111C of the data storage layer 111, and a third cell part 113C of the channel layer 113. The fourth memory cell MC4 may include a fourth gate electrode layer 203d, a fourth memory part 111D of the data storage layer 111, and a fourth cell part 113D of the channel layer 113. The first to fourth cell parts 113A, 113B, 113C, and 113D may be isolated from each other by interlayer insulating layers 105.

Hereinafter, a write operation on the second memory cell MC2 will be described with reference to FIGS. 9A and 9B. A voltage may be applied to a first source/drain pillar 135 and a second source/drain pillar 137, thereby allowing a current having a predetermined magnitude to flow through the channel layer 113. Subsequently, a first write voltage, equal to or higher than a predetermined threshold voltage, may be applied to the second gate electrode layer 203b. No voltage may be applied to the first gate electrode layer 203a, the third gate electrode layer 203c, and the fourth gate electrode layer 203d, or a voltage having a magnitude that is lower than the threshold voltage may be applied to the first gate electrode layer 203a, the third gate electrode layer 203c, and the fourth gate electrode layer 203d. The first write voltage may have negative polarity. Accordingly, an electrical polarization in a predetermined direction may be induced inside the second memory part 111B by an electric field that is applied between the second gate electrode layer 203b and the channel layer 113. Afterwards, when the first write voltage is not applied, a first residual polarization Di1 may be formed at the second memory part 111B. The first residual polarization Di1 may have a first orientation from the channel layer 113 to the second gate electrode layer 203b.

In addition, a write operation on the third memory cell MC3 will be described with reference to FIGS. 9A and 9B. A voltage may be applied to the first source/drain pillar 135 and the second source/drain pillar 137, thereby allowing a current having a predetermined magnitude to flow through the channel layer 113. Subsequently, a second write voltage that is equal to or higher than a predetermined threshold voltage may be applied to the third gate electrode layer 203c. No voltage may be applied to the first gate electrode layer 203a, the second gate electrode layer 203b, and the fourth gate electrode layer 203d, or a voltage having a magnitude that is lower than the threshold voltage may be applied to the first gate electrode layer 203a, the second gate electrode layer 203b, and the fourth gate electrode layer 203d. Accordingly, an electrical polarization in a predetermined direction may be induced inside the third memory part 111C by an electric field applied between the third gate electrode layer 203c and the channel layer 113. Afterwards, when the second write voltage is not applied, a second residual polarization Di2 may be formed at the third memory part 111C. The second residual polarization Di2 may have a second orientation from the third gate electrode layer 203c to the channel layer 113.

A read operation on the non-volatile memory device including the first to fourth memory cells MC1, MC2, MC3, and MC4 may be performed as follows. In an example, each of read operations on the second memory cell MC2 and the third memory cell MC3 will be described. First, a predetermined reference voltage may be applied to the first to fourth gate electrode layers 203a, 203b, 203c, and 203d. The reference voltage might not change a polarization state in the first to fourth memory parts 111A, 111B, 111C, and 111D. The reference voltage may be a sufficiently high voltage at which all transistors of the first to fourth memory cells MC1, MC2, MC3, and MC4 can be turned on. Accordingly, a conductive channel may be formed along the Z direction inside the channel layer 113. Subsequently, when a voltage is applied to the first source/drain pillar 135 and the second source/drain pillar 137, a channel current having a constant magnitude can be secured between the first source/drain pillar 135 and the second source/drain pillar 137, regardless of a residual polarization state that is stored in the first to fourth memory parts 111A, 111B, 111C, and 111D.

Subsequently, the magnitude of a gate voltage that is applied to the second gate electrode layer 203b, corresponding to the second memory cell MC2 to be read, may be changed. Specifically, while the magnitude of the gate voltage is decreased to be smaller than the magnitude of the reference voltage, a limit magnitude of a gate voltage capable of securing a current having the same magnitude as the channel current may be read.

Meanwhile, in the same manner, after the channel current flows between the first source/drain pillar 135 and the second source/drain pillar 137, the magnitude of a gate voltage that is applied to the third gate electrode layer 203c, corresponding to the third memory cell MC3 to be read, may be changed. While the magnitude of the gate voltage is decreased to be smaller than the magnitude of the reference voltage, a limit magnitude of a gate voltage may be read. The limit magnitude of the gate voltage may be a magnitude capable of securing a current having the same magnitude as the channel current.

In an example, as shown in FIGS. 9A and 9C, when the first residual polarization Di1 is stored in the second memory part 111B corresponding to the second memory cell MC2, the first residual polarization Di1 may distribute positive charges in the second memory part 111B that is adjacent to the second gate electrode layer 203b and may distribute negative charges in the second memory part 111B that is adjacent to the channel layer 113. A limit magnitude of the gate voltage that is applied to the second gate electrode layer 203b, which can secure a current having the same magnitude as the channel current, may be measured.

In another example, as shown in FIGS. 9A and 9C, when the second residual polarization Di2 is stored in the third memory part 111C corresponding to the third memory cell MC3, the second residual polarization Di2 may distribute negative charges in the third memory part 111C that is adjacent to the third gate electrode layer 203c and may distribute positive charges in the third memory part 111C that is adjacent to the channel layer 113. A limit magnitude of the gate voltage that is applied to the third gate electrode layer 203c, which can secure a current having the same magnitude as the channel current, may be measured.

Meanwhile, based on a polarity of charges that are disposed adjacent to the channel layer 113, the limit magnitude of the gate voltage corresponding to the third memory cell MC3 in which the second residual polarization Dig is stored may be smaller than the limit magnitude of the gate voltage corresponding to the second memory cell MC2 in which the first residual polarization Di1 is stored. As described above, a limit magnitude of a gate voltage corresponding to a memory cell to be read is measured, thereby identifying residual polarization information stored in the corresponding memory cell. As a result, signal information stored in the corresponding memory cell can be read.

In accordance with various embodiment of the present disclosure, there may be provided a non-volatile memory device capable of increasing a degree of integration of memory cells and an operation speed and reducing signal interference between adjacent memory cells in a structure in which the memory cells are stacked in a direction perpendicular to a substrate.

What is claimed is:

1. A non-volatile memory device comprising:
a substrate;
a gate structure including a plurality of gate electrode layers and a plurality of interlayer insulating layers, which are alternately stacked in a vertical direction over the substrate, the gate structure including a hole pattern;
a data storage layer disposed inside the hole pattern; and
a channel layer disposed on the data storage layer inside the hole pattern,
wherein the channel layer is disposed at each of different levels isolated from each other in the vertical direction by the plurality of interlayer insulating layers.

2. The non-volatile memory device of claim 1, wherein each of the data storage layer and the channel layer is discontinuous in the vertical direction, each of the data storage layer and the channel layer being formed at levels in which each of the plurality of gate electrode layers is formed.

3. The non-volatile memory device of claim 1, wherein, in the gate structure, the plurality of interlayer insulating layers protrude farther into the hole pattern compared to the gate electrode layers.

4. The non-volatile memory device of claim 1, wherein the data storage layer is disposed along a side surface of the hole pattern,
wherein the channel layer is disposed along a side surface of the data storage layer,
wherein the hole pattern includes a concave part that is defined at the same level as each of the plurality of gate electrode layers, the concave part being defined between the plurality of interlayer insulating layers that overlap with each other in the vertical direction, and
wherein the data storage layer and the channel layer are disposed in the concave part.

5. The non-volatile memory device of claim 1, wherein the data storage layer includes ferroelectrics.

6. The non-volatile memory device of claim 1, further comprising:
a first insulating pillar disposed in a central region of the hole pattern; and
a first source/drain pillar and a second source/drain pillar penetrating the first insulating pillar.

7. The non-volatile memory device of claim 6, further comprising a second insulating pillar between the first source/drain pillar and the second source/drain pillar.

8. The non-volatile memory device of claim 6, wherein the first source/drain pillar and the second source/drain pillar penetrate a portion of the channel layer.

9. The non-volatile memory device of claim 1, further comprising at least one of a dielectric layer and a metal layer, which are disposed between the data storage layer and the channel layer.

10. The non-volatile memory device of claim 9, wherein the data storage layer includes ferroelectrics, and
wherein the dielectric layer includes an insulating material.

11. A non-volatile memory device comprising:
a gate structure including a plurality of gate electrode layers and a plurality of interlayer insulating layers, which are alternately stacked in a vertical direction over a substrate;
a channel layer disposed on the substrate, the channel layer disposed adjacent to each of the plurality of gate electrode layers of the gate structure;
a data storage layer disposed between each of the plurality of gate electrode layers and the channel layer; and
a first source/drain pillar and a second source/drain pillar penetrating the gate structure,
wherein each of the data storage layer and the channel layer is discontinuous in the vertical direction, each of the data storage layer and the channel layer being formed at levels in which each of the plurality of gate electrode layers is formed.

12. The non-volatile memory device of claim 11, wherein the channel layer and the data storage layer are disposed between the plurality of interlayer insulating layers.

13. The non-volatile memory device of claim 11, wherein the data storage layer includes ferroelectrics.

14. The non-volatile memory device of claim 11, further comprising:
a first insulating pillar penetrating the gate structure; and
a second insulating pillar between the first source/drain pillar and the second source/drain pillar,
wherein the first source/drain pillar and the second source/drain pillar penetrate the first insulating pillar.

15. The non-volatile memory device of claim 11, wherein the first source/drain pillar and the second source/drain pillar penetrate a portion of the channel layer.

16. The non-volatile memory device of claim 11, wherein the plurality of interlayer insulating layers include a first interlayer insulating layer and a second interlayer insulating layer, which are adjacent to each other in the vertical direction, and
wherein the channel layer and the data storage layer are disposed between the first interlayer insulating layer and the second interlayer insulating layer.

17. The non-volatile memory device of claim 11, further comprising at least one of a dielectric layer and a metal layer, which are disposed between the data storage layer and the channel layer.

18. The non-volatile memory device of claim 17, wherein the data storage layer includes ferroelectrics, and
wherein the dielectric layer includes an insulating material.
